(19) United States
(12) Patent Application Publication
(10) Pub. No.: US 2005/0156664 A1
(43) Pub. Date: Jul. 21, 2005

(54) Class-D line driver arrangement

(76) Inventors: Torbjorn Randahl, Nacka (SE); Carl-Mikael Johansson, Stockholm (SE); Stefan Barkaro, Akersberga (SE); Bo Bokinge, Bromma (SE); Lars Karlsson, Upplands Vasby (SE)

Correspondence Address: JENKINS, WILSON & TAYLOR, P. A., 3100 TOWER BLVD, SUITE 1400, DURHAM, NC, 27707, US

(21) Appl. No.: 10/760,614

(22) Filed: Jan. 20, 2004

(51) Int. Cl. H03F 3/217

(52) U.S. Cl. 330/251

(57) ABSTRACT

Line driver arrangement comprising a class-D switching amplifier having a switching frequency for receiving an input transmit signal and outputting an amplified transmit signal and a transformer having a predetermined leakage inductance for receiving the amplified transmit signal and outputting a transform signal as an output transmit signal. The leakage inductance is predetermined for low-pass filtering of the amplified transmit signal. The line driver arrangement reduces the number of additional discrete inductances, capacitances and or resistor for forming low-pass filters significantly. The inventive line driver arrangement is particularly power-efficient due to the included class-D switching amplifier. The predetermined leakage inductance leads to a suppression of a resonance due to the switching frequency of the class-D amplifier in the power spectral density. Hence, the inventive line driver arrangement complies at least with the ADSL PSD mask requirements.

### BACKGROUND OF THE INVENTION

The invention relates to a line driver arrangement utilizing class-D power amplifiers, in particular for a DSL line driver, and a transformer for use therein.

Digital subscriber lines (DSL) provide the key technologies in our days and help to improve the speed of communications networks. DSL offers extremely fast data transfer on existing copper-based telephone lines. In DSL, broad-band data signals are transmitted on significantly higher frequencies than the traditional narrow-band telephone signals. Since both types of signals, the narrow-band telephone signals and the broad-band data signals, are transmitted over the same subscriber line, splitter devices are provided for splitting and recombining the two types of signals at both ends of the subscriber line: first at the central office or switching center, and second at the end terminals at the subscriber location.

FIG. 1 shows schematically the topology of such an audio telephone network coexisting with a data overlay network.

A central office CO is coupled over the subscriber lines SL1, SL2, . . . SLN to the subscribers S1, S2, . . . SN, wherein at each location splitter devices SPO, SP1, SP2, . . . SPN are provided for separating and combining the DSL broad-band and telephone narrow-band signals.

The signals generated at the central office CO and at the subscriber locations have to fulfill certain requirements. An exemplary standard for “asymmetric digital subscriber line (ADSL) transceivers provides the ITU-T Recommendation G.992.1 (06/99), series G: Transmission systems and media, digital systems and networks. A common line code for transmitting digital data on the asymmetric digital subscriber line is provided by discrete multitone modulation (DMT). In DMT, a given frequency range for data transmission is resolved into a number of narrow-frequency bands for use as individual data links. In ADSL, data transmission occurs roughly between 20 kHz and 1 MHz.

The power spectral density (PSD) of a line code defines the distribution of the line codes power in the frequency domain. Because the frequencies used in the DSL standard must not interfere with other applications in the same frequency band, e.g. radio transmission, so-called PSD masks are introduced. A PSD mask is a template that specifies the maximum PSD allowable for a line code. PSD masks are used as guidelines for the design and implementation of a DSL technology.

FIG. 2 shows a transmit PSD mask according to the ITU-T G992.1 recommended ADSL standard.

The transmit ADSL PSD mask is piecewise continuous and requires −97.5 dBm/Hz up to 4 kHz with a maximum power in the 0-4 kHz band of 15 dB, a slope of 21 dB/octave between 4 (corresponding to −92.5 dB/Hz peak requirement) and 24.875 kHz (correponding to −36.5 dB/Hz peak requirement), −36.5 dBm/Hz between 25.875 and 1104 kHz, a negative slope of −36 dB/oct between 1104 and 3093 kHz and −90 dBm/Hz above 3093 kHz as a peak requirement (PR). Certain standards even require that the power spectral density is below −110 dBm/Hz above 4545 kHz. Further, the maximum power in any 1 MHz wide sliding frequency window above 4545 kHz must be below −50 dBm, and the maximum transmitted total power must not be more than 19.8 dBm between 25.875 kHz and 1104 kHz.

In order to transmit the ADSL data signals over the telephone line that consists of a pair of copper wires—also named as subscriber loop or twisted pair line—the central office must be provided with line drivers. The line drivers compensate for the attenuation of lines and they have to comply with the PSD mask requirements. A line driver has to amplify the line-coded ADSL signal in a way that it is received downstream at the subscriber locations with a sufficient intensity. Similarly, line drivers should be provided at the subscriber locations for transmitting ADSL data upstream to the central office. Both line drivers need to comply with similar requirements with respect to the PSD masks given by the relevant standards.

A basic component of a line driver is a power amplifier for amplifying the DSL signal which is to be transmitted over the telephone line.

Traditionally, linear class-AB amplifiers were used. However, driving transistors in a class-AB amplifier are biased to operate in their linear region which results in that they are always in an on-state and draw precious quiescent current. This results in an inefficient power dissipation. For example, a state-of-the-art class-B line driver consumes 750 mW when transmitting 100 mW which is a power efficiency of only 13%.

A way to improve the power efficiency of a power amplifier is to operate the output transistors as switches. FIG. 3 shows a schematic of such a class-D amplifier in principle.

The schematic class-D amplifier CDA comprises a comparator CP for receiving a triangle wave signal T1 providing a switching frequency FS, that is generated by a triangle wave generator TG, and an input signal S1. The comparator CP compares the triangle wave T1 with the input signal S1 to create a variable duty cycle square wave signal S2. In effect, a pulse train is created with a duty cycle proportional to the input signal S1 level. This pulse width modulated signal S2 is coupled to the gates of the complementary output transistors M1, P1 wherein their respective source drain paths are connected in series between the supply voltage VDD and ground GND. The amplified output signal S3 is tapped at a node between the source drain paths.

In effect, the pulse width modulated signal with a duty cycle proportional to the input signal level turn the complementary output transistors M1, P1 on and off at a switching frequency FS that is much greater than the frequency of the input signal S1. Hence, power is sufficiently delivered from the power supply to the load.

Line drivers employing class-D power amplifiers achieve a power efficiency of about 25%. However, a drawback of class-D amplifiers is that a low-pass filter which removes the high-frequency carrier or switching frequency FS must be provided. Therefore, inductances and capacities need to be properly located in a line driver arrangement to ensure its effectiveness.

FIG. 4 shows a state-of-the-art class-D line driver arrangement in principle as it is similarly disclosed in the international patent application WO03107532.

The line driver LD of prior art comprises a differential class-D switching amplifier DCDA operating at a switching frequency FS which receives the input transmit signal Z1 being generated by the central office CO. The dual line transmit signal Z1 is amplified and output as an amplified transmit signal Z2 by the amplifier DCDA. A low-pass filter LPF comprising an inductance L1, L2 in each line of the dual line 12-1, 12-2 and a capacity C connected between the two lines of the dual line 12-1, 12-2 filters the amplified transmit signal Z2. The amplified and filtered signal is coupled to the dual line subscriber line 14-1, 14-2 through a transformer T as an output transmit signal Z3.

The low-pass filter LPF comprising at least two inductances and the capacitance is mandatory to suppress signal elements in the amplified transmit signal Z3 that stem from the switching frequency FS of the class-D amplifier DCDA. The switching frequency FS may be in the region around 10 MHz which is sufficiently far away from the carrier frequencies of the ADSL data links. Hence, the low pass filter in the line driver arrangement must be tuned to provide a power spectral density that is in compliance with an ADSL standard. To this end the PSD portion above 3093 kHz must be at least below −90 dBm/Hz.

It is a disadvantage that the inductances L1 and L2 must be placed on a circuit board carrying the line driver arrangement. This may lead to additional heat dissipation, the inductances require additional assembling steps and considerable amount of space. Thus, additional costs are created by the use of discrete inductances on a circuit board for a line driver arrangement comprising a class-D power amplifier over the gain in power efficiency.

It is therefore an object of the current invention to provide a small, cost-efficient line driver arrangement with low power consumption and having only few discrete components.

### BRIEF SUMMARY OF THE INVENTION

This object is met by a class-D line driver arrangement having the features of claim 1 and a transformer for use in an inventive line driver arrangement having the features of claim 13.

The inventive line driver arrangement comprises a class-D switching amplifier having a switching frequency FS, said class-D amplifier receiving an input transmit signal, and outputting an amplified transmit signal. The inventive arrangement comprises further a transformer having a predetermined leakage inductance for receiving the amplified transmit signal and outputting a transformed signal as an output transmit signal. The leakage inductance of the transformer is predetermined for low-pass filtering of the amplified transmit signal.

The invention further provides a transformer for use in a line driver arrangement, wherein the line driver arrangement comprises an amplifier for receiving an input transmit signal and outputting an amplified transmit signal. The inventive transformer has a predetermined leakage inductance and/or stray capacitance, and the leakage inductance and/or stray capacitance is predetermined for low-pass filtering of the amplified transmit signal.

The basic idea of the invention is to refrain from using discrete inductances, e.g. coils, or at least reducing the number of discrete elements in the line driver arrangement, and instead utilizing the present leakage inductance of the transformer for low-pass filtering. This idea makes a line driver arrangement smaller, having only few discrete components and therefore being cost-efficient. The use of the class-D amplifier ensures low power consumption, but at the same time complies at least with the ADSL PSD mask requirements.

In a preferred embodiment of the line driver arrangement according to the invention, the leakage conductance is predetermined to minimize a resonance at a resonance frequency in the power spectral density of the line driver arrangement wherein the resonance is caused by the switching frequency of the class-D amplifier. It is a particular advantage that the contributions from the switching frequency in the amplified output transmit signal are reduced because in this way the PSD may be shaped more easily according to a relevant PSD mask.

Preferably, the signals are dual line signals being ADSL signals comprising discrete multitone modulated signals and propagate on a dual line coupling the class-D amplifier and the transformer. The line driver arrangement is preferably part of an ADSL transceiver and complies with an ADSL and/or ADSL plus-Standard.

In another favorable embodiment of the inventive line driver arrangement, a capacitance is connected between the two lines carrying the dual line signal between the class-D amplifier and the transformer. Preferably, a leakage inductance and the capacitance form a low-pass filter having a cutoff frequency that is lower than the resonance frequency that may be caused by the switching frequency of the class-D amplifier.

Another preferred embodiment of the inventive line driver arrangement comprises two capacitances that are connected in series between the two lines between the class-D amplifier and the transformer wherein a node between the two capacitances is connected to a reference voltage. By tuning the reference voltage the zero point of differential signals can be shift and calibrated.

In an alternative embodiment, the transformer further has a stray capacitance that is predetermined to minimize the resonance in the power spectral density of the line driver arrangement. It is an advantage of this preferred embodiment that a low-pass filter for cutting off contributions to the amplified output transmit signal, the contributions stemming from the switching class-D amplifier, is already incorporated into the transformer of the line driver arrangement. Hence, only a minimum of discrete electronic devices are needed for a line driver. Therefore, the line driver becomes small, cost-efficient and simple to build on a circuit board.

In another preferred embodiment of the line driver arrangement according to the invention, a further low-pass filter is coupled between the class-D amplifier and the transformer. The inclusion of a further low-pass filter may improve the filter properties and lead to the compliance of even stricter PSD mask requirements than stated above.

### BRIEF DESCRIPTION OF THE SEVERAL VIEWS OF THE DRAWING

In the following the invention is explained with reference to the schematic use of the appended drawings. It shows

FIG. 1 a schematic DSL network;

FIG. 2 a principle power spectral density mask for DSL;

FIG. 3 a schematic diagram of a switching amplifier;

FIG. 4 a schematic diagram of a class-D line driver according to the prior art;

FIG. 5 a schematic block diagram of the inventive class-D line driver arrangement;

FIG. 6 a schematic diagram of a first preferred embodiment of the inventive line driver arrangement;

FIG. 7 a schematic diagram of a second preferred embodiment of the inventive line driver arrangement; and

FIG. 8 a power spectral density in principle according to an inventive class-D line driver arrangement.

In all of the views of the drawing, equal or functionally equivalent elements are referenced with the same reference characters, if not otherwise indicated.

### DETAILED DESCRIPTION OF THE INVENTION

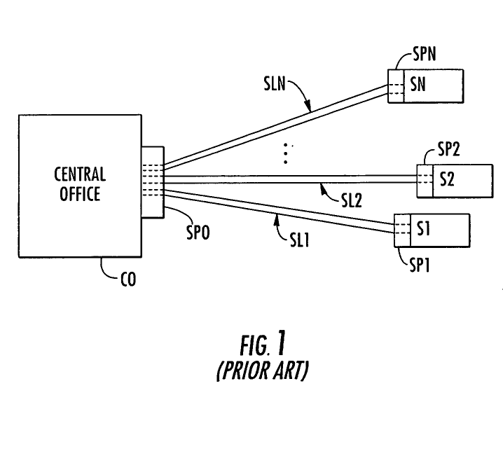

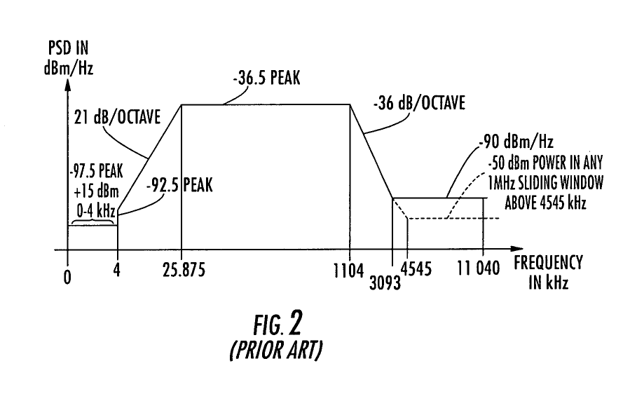

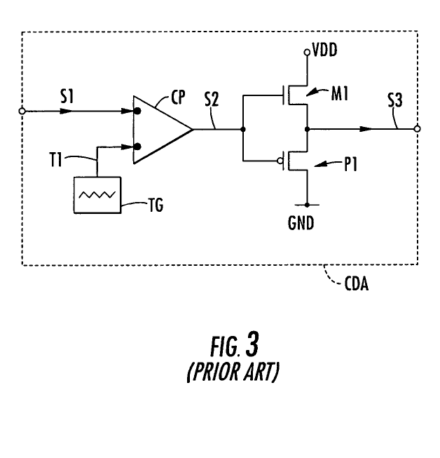

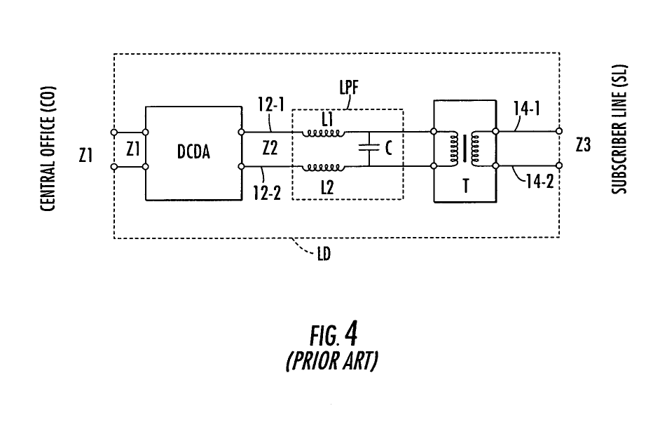

FIG. 1-4 are already depicted in the introduction of the specification.

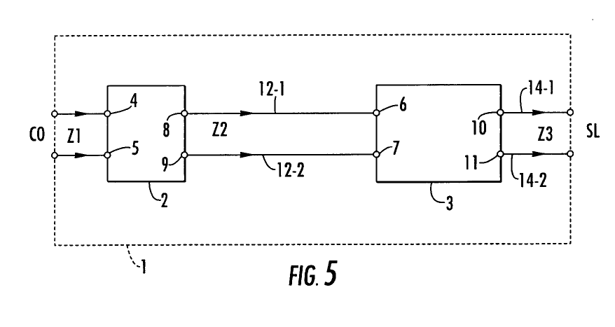

FIG. 5 shows a block diagram of the inventive line driver arrangement.

The inventive line driver arrangement 1 comprises a class-D switching amplifier 2 having two input terminals 4, 5 and two output terminals 8, 9. The class-D amplifier 2 has a switching frequency FS and receives an input transmit signal Z1 in/from a central office CO and outputs an amplified transmit signal Z2 to a dual line 12-1, 12-2. The line driver arrangement further comprises a transformer 3 that has a predetermined leakage inductance for receiving the amplified transmit signal Z2 on its two inputs 6, 7. The transformer couples the amplified transmit signal Z2 to the dual telephone line 14-1, 14-2. The transformer receives the amplifier transmit signal Z2 on its input terminals 6, 7 and outputs the output transmit signal Z3 on its output terminals 10, 11 to a subscriber line SL. A leakage inductance of the transformer 3 is predetermined for low-pass filtering of the amplified transmit signal Z2.

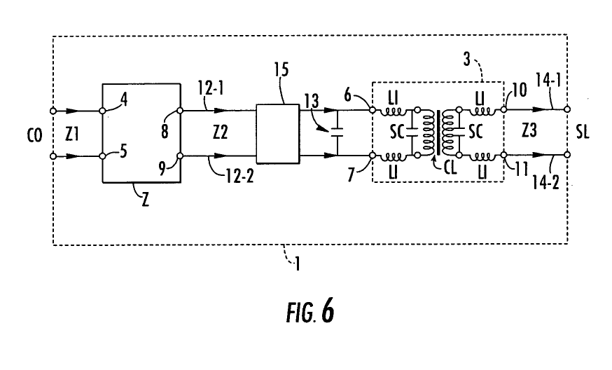

FIG. 6 shows a preferred embodiment of the inventive line driver arrangement 1. The preferred embodiment basically comprises the same elements as in FIG. 5, but additionally comprises a capacity 13 between the two lines of the dual line 12-1, 12-2 between the class-D amplifier 2 and the transformer 3. The line driver arrangement 1 further comprises a complementary low-pass filter 15 between the class-D amplifier 2 and the transformer 3. The transformer 3 is drawn as its equivalent circuit diagram having a leakage inductance LI coupled between each input terminal 6, 7, output terminal 10, 11 and the respective transformer coil CL. The equivalent circuit diagram of the transformer 3 also shows stray capacitances SC between the two input terminals 6, 7 and between the two output terminals 10, 11.

In the central office, a discrete multitone modulated signal Z1 as an ADSL signal is created and fed into the class-D amplifier 2 on its input terminals 4, 5. The class-D switching amplifier 2 amplifies the transmit signal Z1 and outputs the amplified transmit signal Z2 to the dual line comprising of the lines 12-1 and 12-2. The same amplified transmit signal Z2 is filtered through a complementary low-pass filter 15 that already pre-shapes the amplified transmit signals according to a certain PSD mask. The leakage inductance LI and the stray capacitance SC of the transformer 3 form together with a capacitor 13 a further low-pass filter wherein the leakage inductance LI and the capacitances 13, SC are predetermined to minimize a resonance at a resonance frequency RF in the power spectral density PSD of the line driver arrangement 1. Here, the resonance which is caused by the switching frequency FS of the class-D amplifier 2. The thereby processed amplified transmit signal Z2 is then coupled to the dual line 14-1, 14-2, that eventually forms the subscriber line SL, as the output transmit signal Z3.

Although the switching frequency FS of the class-D amplifier 2 gives rise to a resonance in the power spectral density of the line driver arrangement 1, the particular choice of the leakage inductance LI, stray capacitance SC, and the capacity 13 leads to a significant suppression of the resonance. Hence, without resorting to individual discrete inductances in the line driver arrangement 1, a power spectral density is achieved that complies with a PSD mask required by an ADSL standard. With respect to prior art line drivers, a line driver employing the inventive line driver arrangement 1 is smaller, shows a low power consumption due to the class-D amplifier, contains only a few discrete components and is therefore more cost-efficient than prior art line drivers.

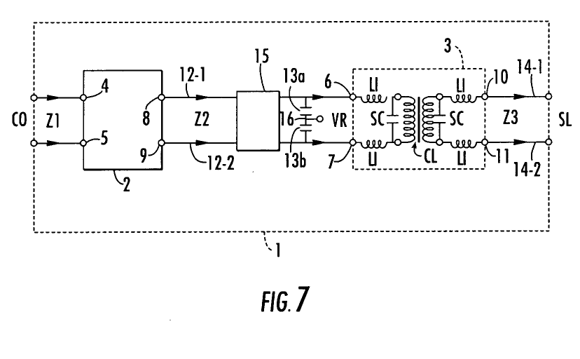

FIG. 7 shows a second preferred embodiment of the inventive line driver arrangement 1. The second preferred embodiment comprises the same elements as in FIG. 6, wherein two capacitances 13a, 13b are connected in series between the two lines 12-1, 12-2 between the class-D amplifier 2 and the transformer 3 instead of a single one 13. A node 16 between the two capacitances 13a, 13b is connected to a reference voltage VR. The reference voltage lies preferably in the range between ground GND and a positive and/or negative supply voltage. By changing the reference voltage VR the zero point of the differential signals on the lines 12-1, 12-2 is tuned. Since the transformer 3 may exhibit a non-symmetric distribution of its stray capacitance. The use of the reference voltage VR allows to calibrate the differential signals on the and hence leads to a better signal quality and improved low pass filtering.

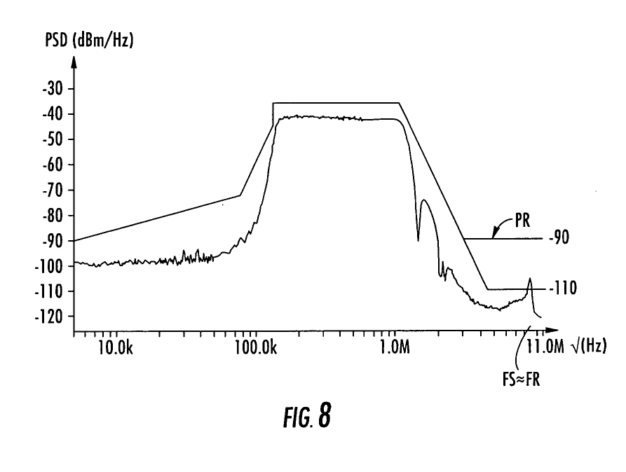

FIG. 8 shows an exemplary power spectral density of an inventive class-D line driver arrangement and a respective ADSL PSD mask.

The critical region of the PSD of the class-D line driver according to the invention are the frequencies around the switching frequency which is chosen to be 10 MHz. Switching frequencies other than 10 MHz may be realized in a class-D power amplifier. However, the switching frequency FS should be higher than the frequencies of the ADSL channels. The PSD clearly shows the resonance around 10 MHz which is, however, below −90 dBm/Hz and hence complies with the peak requirement of the ADSL standard. The strong attenuation or suppression of the resonance at the resonance frequency FR is realized by increasing the leakage inductance of a conventional transformer.

Usually, transformers are constructed to have a leakage inductance as low as possible. For instance, investigations of the applicant show that an increase of a leakage inductance of 2 μH to 18 μH of a typical transformer device used in ADSL line drivers is sufficient to create a low pass filter for fulfilling the PSD mask requirements. The inventive increase of the leakage inductance of the transformer leads to the excellent low-pass filtering effect and hence reduces the number of discrete elements, as coils, capacitors and/or resistors etc., in the remainder of the line driver arrangement. Additional fine tuning of the inventive low-pass filtering in the leakage inductance of a transformer may be achieved by a controlled change of the distributed capacitance or stray capacitance of the transformer.

The inventive concept of transferring discrete inductances for low-pass filtering of an amplified ADSL signal into the leakage conductance and/or stray capacitance of a transformer in a line driver leads to small and cost-efficient line driver cards that contain only few discrete components. The resonance or peak at the switching frequency in the power spectral density of such a line driver comprising a power-efficient class-D amplifier (switched amplifier) is sufficiently suppressed by the low-pass filtering performed the stray capacitance, the leakage inductance and optional capacitors. The PSD also complies with at least the ADSL PSD mask requirement.

Although the current invention has been explained with reference to particular embodiments of the inventive line driver arrangement, the scope of the invention is not intended to be limited to this, but rather defined by the appended claims. It is believed that the inventive line driver arrangement may be modified by the skilled person without departing from the spirit of the invention. In particular, the line driver arrangement may be part of a transceiver system for ADSL or other broadband applications. The change and control of the leakage inductance and/or the stray capacitance of transformers may be realized by a variety of peculiar techniques, e.g. by changing the dimension of the gap between the turns of the transformer, adding particular isolation materials or dielectrics, choosing particular geometries or materials.

### REFERENCE CHARACTERS

CO central office
SP0, SP1, SP2, . . . , SPN splitter device
SL1, LS2, . . . , SLN subscriber line
S1, S2, . . . , SN subscriber
PSD power spectral density
PR peak requirement
VDD supply voltage
GND ground
TG triangle wave generator
T1 triangle wave signal
S1 input signal
CP comparator
S2 pulsed signal
M1, P1 transistor
S3 amplified signal
CDA class-D amplifier
Z1 transmit signal
Z2 amplified transmit signal
Z3 output transmit signal
DCDA differential class-D amplifier
L1, L2 inductances
C capacitor
LPF low-pass filter
T transformer
LD line driver
VR reference voltage
1 line driver arrangement
2 class-D amplifier
3 transformer
4, 5, 6, 7 input terminals
8, 9, 19, 11 output terminals
12-1, 12-2 dual line
13, 13a, 13b capacitor
14-1, 14-2 dual line
15 low-pass filter
16 node
LI leak inductance
SC stray capacitance
CL transformer coil
FS switching frequency
FR resonance frequency

1. A Line driver arrangement comprising:
(a) a class-D switching amplifier having a switching frequency, said class-D amplifier receiving an input transmit signal and outputting an amplified transmit signal;
(b) a transformer having a predetermined leakage inductance for receiving the amplified transmit signal and outputting a transformed signal as an output transmit signal;
wherein the leakage inductance is predetermined for low pass filtering of the amplified transmit signal.

2. Line driver arrangement according to claim 1, wherein the leakage inductance is predetermined to minimize a resonance at a resonance frequency in the power spectral density of the line driver arrangement, wherein the resonance is caused by the switching frequency of the class-D amplifier.

3. Line driver arrangement according to claim 1, wherein the signals are dual line signals, the class-D amplifier and the transformer each have two input terminals and two output terminals and are connected in series through a dual line.

4. Line driver arrangement according to claim 3, wherein the dual line signals are ADSL signals being discrete multitone modulated signals.

5. Line driver arrangement according to claim 1, wherein at least one capacitance is connected between the two lines between the class-D amplifier and the transformer.

6. Line driver arrangement according to claim 1, wherein two capacitances are connected in series between the two lines between the class-D amplifier and the transformer, and wherein a node between the two capacitances is connected to a reference voltage.

7. Line driver arrangement according to claim 5, wherein the leakage inductance and the capacitances form a low pass filter having a cutoff frequency that is lower than the resonance frequency.

8. Line driver arrangement according to claim 1, wherein the transformer further has a stray capacitance that is predetermined to minimize the resonance in the power spectral density of the line driver arrangement.

9. Line driver arrangement according to claim 1, wherein a low pass filter is coupled between the class-D amplifier and the transformer.

10. Line driver arrangement according to claim 1, wherein the line driver has a power spectral density that complies with an ADSL and/or ADSL+ standard.

11. Line driver arrangement according to claim 1, wherein the line driver is part of an ADSL transceiver.

12. Line driver arrangement according to claim 1, wherein the line driver arrangement further comprises resistances and/or inductances.

13. Transformer for use in a line driver arrangement, said line driver arrangement comprising an amplifier for receiving an input transmit signal and outputting an amplified transmit signal and wherein the transformer has a predetermined leakage inductance and/or stray capacitance, and the leakage inductance and/or stray capacitance is predetermined for low pass filtering of the amplified transmit signal.

14. Transformer according to claim 13, wherein the amplifier is a class-D switching amplifier having a switching frequency.
